(19) United States
(12) Patent Application Publication
(10) Pub. No.: US 2018/0201761 A1
(43) Pub. Date: Jul. 19, 2018

(54) EPOXY RESIN COMPOSITION FOR COPPER CLAD LAMINATE, AND APPLICATION OF EPOXY RESIN COMPOSITION

(71) Applicant: Shengyi Technology Co., Ltd., Guandong (CN)

(72) Inventors: Ying XU, Guangdong (CN); Kehong FANG, Guangdong (CN)

(21) Appl. No.: 15/743,930

(22) PCT Filed: Dec. 7, 2015
(86) PCT No.: PCT/CN2015/096517

§ 371 Date: Jan. 11, 2018

(30) Foreign Application Priority Data
Aug. 3, 2015 (CN) 201510483488.2

(51) Int. Cl. C08K 5/53; C08K 3/22; C08K 3/30; C08K 5/136; C08G 59/50; C08J 5/24; B32B 5/26; B32B 5/02; B32B 15/14; H05K 1/03

(52) U.S. Cl. CPC C08K 5/53; H05K 2201/012; C08K 3/30; C08K 5/136; C08G 59/5033; C08J 5/24; B32B 5/26; B32B 5/022; B32B 5/024; B32B 15/14; H05K 1/0373; C08K 2201/005; C08K 2003/2227; C08K 2003/3045; C08J 2363/00; B32B 2260/023; B32B 2260/046; B32B 2262/101; B32B 2457/08; C08K 3/22

(57) ABSTRACT

The present invention relates to an epoxy resin composition for a copper clad laminate, and an application of the epoxy resin composition. The epoxy resin composition may be used for the preparation of pre-pregs and copper clad laminates. By respectively using brominated bisphenol A and a phosphorus-containing phenolic aldehyde as bromine and phosphorus sources, and adjusting the proportions of the brominated bisphenol A and the phosphorus-containing phenolic aldehyde within the epoxy resin composition, the bromine content is controlled at 5-12%, the phosphorus content is controlled at 0.2-1.5%, and the flame retardancy achieves the level of UL94 V-0. Pre-pregs and laminates manufactured using the epoxy resin composition have reduced halogen content and improved heat resistance. Substrate pressure resistance is improved, moisture absorption is low, adhesion, reactivity and processability are good, comparative tracking index (CTI)>600V is satisfied, and production costs are significantly reduced.

### TECHNICAL FIELD

The present invention relates to the technical field of laminates, specifically to an epoxy resin composition, especially to an epoxy resin composition for copper clad laminates, as well as a prepreg, a laminate and a printed circuit board prepared therefrom.

### BACKGROUND ART

With the formal implementations of the EU directives of WEEE (Waste Electrical and Electronic Equipment) and RoHS (Restriction of Hazardous Substances), the global electronics industry has entered a lead-free soldering era. The increase of lead-free soldering temperature puts forward higher requirements on the heat resistance and thermal stability of copper clad laminates for printed circuits. Affected by the “green” regulations issued by the European Union, it has been pushed to the front line of controversy whether bromine as a flame retardant element should be used in the field of polymers. Although tetrabromobisphenol A, as a flame retardant, has not been found to have any significant negative impact on the environment, the voice of making it a prohibited substance is increasingly higher. Therefore, the flame retardant dependence on bromine in the future will be necessarily and gradually reduced. It is even more urgent to find a technology of copper clad laminates having better heat resistance, low moisture absorption and less dependence on bromine.

Bromine is mostly used for flame retardancy in traditional FR4. Bromine has a high flame retardant efficiency, and flame retardant substances such as tetrabromobisphenol A are inexpensive and easy to be popularized. However, the total bromine content in ordinary FR4 needs to typically reach 15% or higher (the mass ratio of bromine to the organic solids in the plates) so as to achieve UL94V-0 level, if only bromine is used for flame retardancy. Higher bromine content is not only contrary to the environment-friendliness, but also lead to a serious decline in the heat resistance of the material itself because C—Br bond is easy to break. Organic matters with high bromine contents are not conducive to work under high temperature and pressure, in wet and easily contaminated environment, since bromine will accelerate the leakage failure of materials between the two circuits of circuit boards. Thus, the materials can be made to adapt to harsh surroundings, such as high pressure and humidity and the like by reducing the bromine content. For example, both CN101654004A and CN102382420A disclose that, starting from epoxy resins and fillers, the use of epoxy resin containing a bromine content which is reduced to 10-15% in the resin system or specially modified, and the addition of a large amount of inorganic fillers, such as aluminum hydroxide, makes the materials adapt to harsh environments. However, a too large amount of aluminum hydroxide will decrease the heat resistance. This is because aluminum hydroxide has a low thermal decomposition temperature and starts to dehydrate at 200° C.; the PCB soldering temperature ranges from 245-260° C., which easily makes the final plates have delamination and blistering at high temperature, so as to affect the reliability of the products.

Phosphorus flame retardants can also achieve the purpose of flame retardancy. Since the phosphorus flame retardant system contains no bromine, it has a much better heat resistance than the bromine flame retardant system. However, phosphorus is easy to absorb moisture. The plates merely using phosphorus element for flame retardancy have a higher moisture absorption, which is not conducive to the electrical property stability of the plates. At present, phosphorus-based flame retardants generally have higher price and higher cost pressure. Therefore, it is not possible to discard brominated flame retardants for cost reasons, although there is a high voice for halogen-free flame retardants. CN102093670A discloses a process for achieving flame retardancy by using a phosphorus-containing phenolic aldehyde containing 9,10-dihydro-9-oxa-10-phosphaphenanthrene-10-oxide (DOPO) structure. Although DOPO has a lower water absorption than phosphate, the moisture absorption rate thereof has not been better improved since the phosphorus content is also above 2% due to its large amount.

In the current CCL (copper clad laminate) formulations, the bromine flame retardant system or phosphorus flame retardant system is mostly used. In the bromine flame retardant system, the bromine content is higher, and usually above 15% to achieve flame retardancy. But higher bromine content leads to poor heat resistance, and the comparative tracking index (CTI) is also hard to reach 600V. Due to higher phosphorus content, the phosphorus flame retardant system will have the disadvantage of increased moisture absorption rate.

Although both CN101892027 and CN101808466 disclose using bromine and phosphorus together, they reveal using much nitrile rubber. As compared to epoxy resin, the acrylonitrile structure has a higher water absorption, and the composite substrate has a reduced voltage resistance. In addition, the acrylonitrile structure in nitrile rubber will speed up the decomposition of bromine, and thus be not good for the CTI performance of the bromine-containing system.

Therefore, it is an urgent problem to be solved to find an epoxy resin composition having a low moisture absorption, a high comparative tracking index (CTI) value, and having good heat resistance, cohesiveness, reactivity, and processability.

### DISCLOSURE OF THE INVENTION

The object of the present invention lies in providing an epoxy resin composition, especially an epoxy resin composition for copper clad laminates, as well as a prepreg, a laminate and a printed circuit board prepared therefrom.

In order to achieve the object, the present invention discloses the following technical solutions.

In the first aspect, the present invention provides an epoxy resin composition comprising, based on the weight parts of organic solids,

(A) from 50 to 100 parts by weight of an epoxy resin,

(B) from 2 to 30 parts by weight of a phosphorus-containing phenolic aldehyde,

(C) from 1 to 40 parts by weight of a brominated bisphenol A,

(D) from 10 to 60 parts by weight of other curing agent,

(E) from 0.05 to 1.0 part by weight of a curing accelerator,

wherein the bromine in the epoxy resin composition is in an amount of 5-12% of the weight sum of organic solids in the composition; the phosphorus in the epoxy resin composition is in an amount of 0.2-1.5% of the weight sum of organic solids in the composition.

In the current production of CCL, bromine-containing flame retardant materials, when used alone, cannot achieve flame retardancy unless the bromine content therein is usually 15% or more. However, higher bromine content leads to poor heat resistance, and CTI value is hard to reach 600V. Phosphorus-containing flame retardants, when used alone for flame retardancy, cannot achieve the UL94 V-0 level unless there is a higher phosphorus content. However, a too higher phosphorus content will result in the disadvantage of increased moisture absorption. The present invention discloses, in the way of introducing flame retardant elements, adding phosphorus-containing phenolic aldehyde and brominated bisphenol A at the same time, adjusting the amounts thereof so as to make the bromine content be 5-12% and the phosphorus content be 0.2-1.5%, which not only makes the flame retardancy reach the UL94 V-0 level, but also has a higher heat resistance and can achieve a higher CTI value (CTI>600V) than CCL merely using bromine-containing epoxy resin flame retardant materials for flame retardancy, and has a lower moisture absorption and a longer solder dipping resistance time than CCL merely using phosphorus-containing epoxy resin flame retardant materials for flame retardancy.

In the epoxy resin composition of the present invention, bromine and phosphorus are preferably from phosphorus-containing phenolic aldehyde and brominated bisphenol

Most of the current CCL materials use bromine flame retardant system or phosphorus flame retardant system. In the bromine flame retardant CCLs used in the largest amount, brominated epoxy resins are mostly used as the bromine source. Generally, such CCLs need a very high bromine content to achieve the flame retardancy object. However, since such plates have a higher bromine content, the CTI performance of the materials themselves is severely restricted, and it is very difficult for the bromine-containing system to achieve high heat resistance and high CTI. In halogen-free CCLs, there are many ways to introduce phosphorus, and the mainstream direction is to use phosphorus-containing epoxy or phosphorus-containing phenolic aldehyde. However, such plates have a higher phosphorus content, wherein phosphorus is easy to absorb water. Thus, the water absorption thereof is much higher than that of the bromine flame retardant system.

The present invention discloses using brominated bisphenol A as the source of bromine element, in combination with phosphorus-containing phenolic aldehyde providing phosphorus element. The two can form a cross-linked interpenetrating network, so as to have better synergistic effect. Bromine and phosphorus only in a lower content can make the flame retardancy of the substrates achieve the UL94 V-0 level, further decrease the water absorption of the substrates, have high CTI, and better cohesiveness, processability and processing operability and reduce the dependence of flame retardancy on bromine, so as to be more environmentally friendly.

In the present invention, the epoxy resin is in an amount of 50-100 parts by weight, e.g. 50, 55, 60, 65, 70, 75, 80, 85, 90, 95, 100 parts by weight.

In the present invention, the phosphorus-containing phenolic aldehyde is in an amount of 2-30 parts by weight, e.g. 2, 5, 8, 10, 12, 15, 18, 20, 22, 25, 28, 30 parts by weight.

In the present invention, the brominated bisphenol A is in an amount of 1-40 parts by weight, e.g. 1, 2, 5, 8, 10, 12, 15, 18, 20, 22, 25, 28, 30, 32, 35, 38, 40 parts by weight.

In the present invention, said other curing agent is in an amount of 10-60 parts by weight, e.g. 10, 12, 15, 18, 20, 22, 25, 28, 30, 32, 35, 38, 40, 42, 45, 48, 50, 52, 55, 58, 60 parts by weight.

In the present invention, the curing accelerator is in an amount of 0.05-1.0 part by weight, e.g. 0.05, 0.08, 0.1, 0.2, 0.3, 0.4, 0.5, 0.6, 0.7, 0.8, 0.9, 1.0 part by weight.

In the epoxy resin composition of the present invention, the bromine is in an amount of 5-12%, e.g. 5%, 5.5%, 6%, 6.5%, 7%, 7.5%, 8%, 8.5%, 9%, 9.5%, 10%, 10.5%, 11%, 11.5%, 12%, preferably 5-10%, more preferably 5-8%, of the weight sum of organic solids in the composition.

In the epoxy resin composition of the present invention, the phosphorus is in an amount of 0.2-1.5%, e.g. 0.2%, 0.3%, 0.4%, 0.5%, 0.6%, 0.7%, 0.8%, 0.9%, 1.0%, 1.1%, 1.2%, 1.3%, 1.4%, 1.5%, preferably 0.5-1.5%, more preferably 0.8-1.5%, of the weight sum of organic solids in the composition.

In the present invention, the phosphorus-containing phenolic aldehyde is a phosphorus-containing phenanthrene compound, preferably a phenolic resin corresponding to dihydro-9-oxo-10-phosphaphenanthrene;

preferably, said phosphorus-containing phenolic aldehyde is at least one selected from the following phenolic resins:

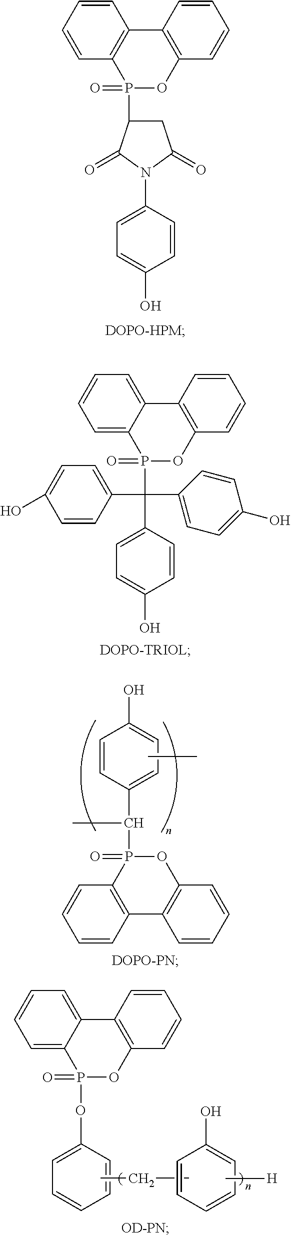

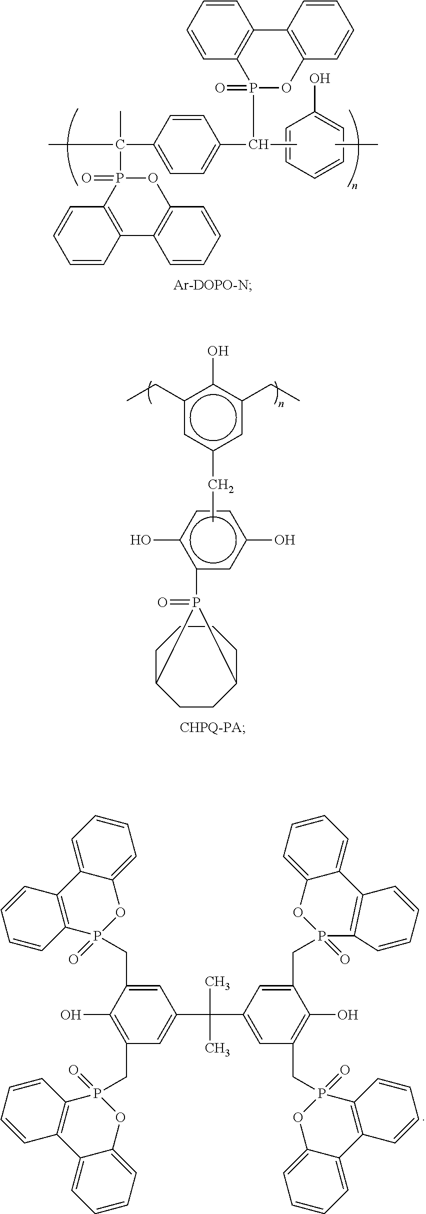

In the present invention, said brominated bisphenol A has the following chemical structural formula:

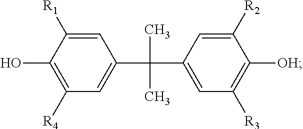

wherein at least one of R₁-R₄ is Br atom; when R₁-R₄ are not Br atom, they are H atom, e.g. R₁ is Br atom, and R₁-R₃ are H atom; or R₁ and R₂ are Br atom, and R₃-R₄ are H atom.

In the present invention, said epoxy resin is anyone selected from the group consisting of bisphenol A epoxy resin, o-cresol novolac epoxy resin, bisphenol A novolac epoxy resin, phenol epoxy resin, dicyclopentadiene epoxy resin, MDI epoxy resin, bisphenol F epoxy resin, bisphenol S epoxy resin, bisphenol F epoxy resin, tetrafunctional epoxy resin, naphthalene epoxy resin and biphenyl epoxy resin, or a mixture of at least two selected therefrom.

In the present invention, said other curing agent is anyone selected from the group consisting of phenolic resin, aromatic diamine-based curing agent, dicyandiamide, aliphatic amine, acid anhydride, active polyester and cyanate, or a mixture of at least two selected therefrom.

Preferably, said phenolic resin is anyone selected from the group consisting of phenol novolac resin, bisphenol A novolac resin, o-cresol novolac resin, triphenol novolac resin, naphthalene novolac resin, biphenyl novolac resin and dicyclopentadiene novolac resin, or a mixture of at least two selected therefrom.

Preferably, said aromatic diamine-based curing agent has the following chemical structural formula:

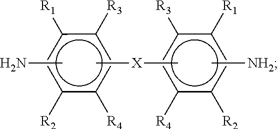

wherein X is selected from the group consisting of

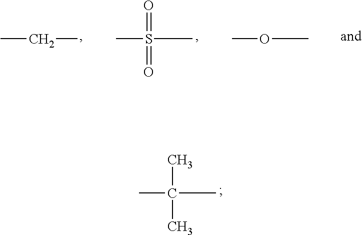

R₃ and R₄ are selected from the group consisting of H, —CH₃ and —C₂H₅; R₂ is selected from the group consisting of H, —CH₃ and —C₂H₅.

In the present invention, said curing accelerator is anyone selected from the group consisting of imidazole curing accelerator, organic phosphine curing accelerator and tertiary amine curing accelerator, or a mixture of at least two selected therefrom.

Preferably, said imidazole curing accelerator is anyone selected from the group consisting of 2-methylimidazole, 2-methyl-4-ethylimidazole, 2-undecylimidazole, 2-phenylimidazole and 1-cyanoethyl-2-ethyl-4-methylimidazole, or a mixture of at least two selected therefrom.

Preferably, said organic phosphine curing accelerator is tributylphosphine and/or triphenylphosphine.

Preferably, said tertiary amine curing accelerator is benzyl dimethyl amine.

In the present invention, the addition amount of the curing accelerator shall not be too much. When the addition amount is too much, the reaction will be fast, so as to be disadvantageous to the process operation and material storage.

In the present invention, the epoxy resin composition further comprises a filler, preferably an inorganic filler.

Preferably, said filler is anyone selected from the group consisting of boehmite, aluminum hydroxide, barium sulfate, calcium fluoride, magnesium hydroxide, silica, glass powder, kaolin, talc powder, mica powder, aluminum oxide, zinc oxide, magnesium oxide, boron nitride, aluminum nitride and calcium carbonate, or a mixture of at least two selected therefrom.

Preferably, said filler has an average particle size of 0.3-20 μm,

Preferably, said filler is in an amount of, based on the sum of organic solids of all components in said epoxy resin composition being 100 parts by weight, from 1 to 200 parts by weight, e.g. 1, 5, 10, 20, 30, 50, 60, 80, 100, 120, 140, 150, 180, 200 parts by weight, preferably from 50 to 100 parts by weight.

The present invention discloses that the addition of the filler, such as aluminum hydroxide, barium sulfate, boehmite and the like, can further improve the CTI of the substrate, and make the CTI of the substrate reach 600V or more.

In order to make said inorganic filler be homogeneously dispersed in the epoxy resin and increase the binding force between the resin and filler, an auxiliary agent may be appropriately added into the epoxy resin composition. The auxiliary agent used therein is an aminosilane coupling agent or an epoxy silane coupling agent. Such coupling agents contain no heavy metal and have no adverse effect on human health. The usage amount thereof is 0.5-2% by weight of the inorganic filler.

Preferably, said epoxy resin composition further comprises a solvent, preferably an organic solvent.

Preferably, said solvent is anyone selected from the group consisting of N,N′-dimethyl-formamide, ethylene glycol ethyl ether, propylene glycol methyl ether, acetone, butanone, methanol, ethanol, benzene and toluene, or a mixture of at least two selected therefrom.

As to the epoxy resin composition of the present invention, a solvent may be used to adjust the viscosity. The aforesaid solvent can adjust the content of solid components in the epoxy resin composition to 40-80%.

In the second aspect, the present invention further provides a prepreg prepared by using the epoxy resin composition stated in the first aspect of the present invention, comprising a base material, and the epoxy resin composition attached thereon after impregnation and drying.

Preferably, said base material is selected from the group consisting of non-woven and woven glass fiber cloth.

In the third aspect, the present invention further provides a laminate comprising the prepreg stated in the second aspect of the present invention.

In the fourth aspect, the present invention further provides a printed circuit board, comprising the laminate stated in the third aspect of the present invention.

As compared to the prior art, the present invention has the following beneficial effects.

(1) In the epoxy resin composition of the present invention, brominated bisphenol A and phosphorus-containing phenolic aldehyde are used respectively as bromine and phosphorus sources, in combination with specific ratio of bromine to phosphorus, which not only make the flame retardancy reach the UL94 V-0 level, but also improve the CTI of the materials which may reach CTI>600V, while effectively controlling costs,

(2) The epoxy resin composition of the present invention has better heat resistance than pure bromine flame retardant system, and lower moisture absorption than pure phosphorus flame retardant system. That is to say, the present invention solves the problems of worse heat resistance of pure bromine flame retardant system, and high moisture absorption of pure phosphorus flame retardant system, and thus has excellent comprehensive performance.

(3) The prepregs and CCLs prepared by using the epoxy resin composition of the present invention have a high glass transition temperature, a high heat resistance, a high peeling strength, a high CTI and better processability, and are suitable for lead-free soldering.

(4) The present invention discloses further decreasing the dependence of the flame retardancy on bromine element, so as to be more environmentally friendly.

### EMBODIMENTS

The technical solution of the present invention is further stated by the following specific embodiments, but is not limited to these embodiments.

Those skilled in the art shall know that said examples are only used for understanding the present invention, and shall not be deemed as specific limitations to the present invention.

Examples Process for Preparing CCLs

Epoxy resin, phosphorus-containing phenolic aldehyde, brominated bisphenol A, and other curing agent, filler and curing accelerator, together with organic solvent, were homogeneously mixed in a stirring and dispersing device. Said epoxy resin composition was pre-impregnated to non-woven or woven glass fiber cloth, and dried in a glue machine (120-180° C.) to prepare semi-cured prepregs for printed circuit boards.

Several sheets of prepreg above were stacked together. One side or both sides of the stacked sheets were laminated with copper foil, and then placed on a laminator at 120-200° C., hot-pressed into a form and prepared into a CCL for printed circuit board processing. Said copper foil can also be replaced with aluminum foil, silver foil or stainless steel foil.

As for CCLs prepared in said examples, performance tests were made for the glass transition temperature, CTI, flame retardancy, solder dipping resistance time, PCT water absorption, 5% thermal weight loss and drilling processability, and further described and stated in the following Examples 1-4 and Comparative Examples 1-7.

The components in the epoxy resin compositions in Examples 1-4 and Comparative Examples 1-5 and contents thereof (parts by weight) are shown in Table 1, wherein the epoxy resin compositions in Table 1 are based on 100% of solid contents. The codes of each component and the corresponding component names are stated as follows.

(A) Epoxy resin

(A1) MDI epoxy resin: 97103, having an epoxy equivalent of 290 g/eq from DOW Chemical;

(A2) tetrafunctional epoxy resin: 1031, having an epoxy equivalent of 210 g/eq from Momentive;

(B) Curing agent

(B1) linear novolac resin: 2812, from Momentive;

(B2) aromatic diamine: 4,4-DDS, from Yinsheng Taiwan;

(C1) Tetrabromobisphenol A: TBBPA, from Albemarle Corporation;

(D1) Phosphorus-containing phenolic aldehyde: 92741, from DOW Chemical;

(E) Filler

(E1) Boehmite: Bengbu Xinyuan Quartz Material Limited Company;

(E2) Aluminum hydroxide: Albemarle Corporation;

(E3) Barium sulfate: Guizhou Redstar

(F) Curing accelerator: 2-E-4MI, from Shikoku Chemicals;

(G) Organic solvent: butanone, from Dow Chemical.

The following methods are used to test the CCLs prepared in Examples 1-4 and Comparative Examples 1-7, and the test methods for each performance parameter are stated as follows.
(A) Glass transition temperature (Tg): on the basis of the differential scanning calorimetry (DSC), tested according to the DSC method as stipulated under IPC-TM-650 2.4.25.
(B) Comparative tracking index (CTI): tested according to the method as stipulated under GB/T 4207-84.
(C) Solder dipping resistance time: impregnating a double-sided copper foil plate having a size of 100×100 mm into a solder tank heated to 288° C., and recording the time from impregnation to delamination and popcorn of the plate.
(D) PCT water absorption: pre-drying the sample, weighing and cooking in a pressure cooker for 4 hours, and observing the mass change rate.
(E) 5% thermal weight loss: heating under nitrogen atmosphere to 500° C. at a heating rate of 5° C./min, and recording the temperature at which the sample mass losses 5%.
(F) Drilling processability: stacking two plates having a thickness of 1.6 mm together, continuously drilling 5000 holes with a 0.3 mm drill at a drilling speed of 110 krpm and a falling speed of 33 mm/s, observing the cutting edge wear of the drill per 1000 holes, and determining the drilling processability according to the wear conditions.
(G) Flame retardancy: tested according to the method under UL 94.
(H) Breakdown voltage: tested according to the IPC standard method.

The test results of the CCLs prepared in Examples 1-4 and Comparative Examples 1-7 are shown in Table 2.

TABLE 1

| | | | | | Comp. | Comp. | Comp. | Comp. | Comp. |
|---|---|---|---|---|---|---|---|---|---|
| | Example | Example | Example | Example | Example | Example | Example | Example | Example |
| Materials | 1 | 2 | 3 | 4 | 1 | 2 | 3 | 4 | 5 |
| A1 | 90 | 90 | 90 | 90 | 90 | 90 | 90 | 90 | 90 |
| C1 | 33 | 15 | 24 | 24 | 40 | 24 | 0 | 10 | 33 |
| D1 | 4 | 28 | 15 | 15 | 0 | 0 | 50 | 2 | 2 |
| A2 | 10 | 10 | 10 | 10 | 10 | 10 | 10 | 10 | 10 |
| B1 | 20 | 20 | 20 | 20 | 20 | 20 | 25 | 20 | 20 |
| B2 | 3 | 6 | 3 | 3 | 3 | 3 | 7 | 3 | 3 |
| F | 0.05 | 0.05 | 0.05 | 0.05 | 0.06 | 0.06 | 0.05 | 0.05 | 0.05 |
| E1 | 40 | 40 | 40 | 0 | 40 | 40 | 40 | 40 | 40 |
| E3 | 20 | 20 | 20 | 0 | 20 | 20 | 20 | 20 | 20 |
| E2 | 10 | 10 | 10 | 0 | 10 | 10 | 10 | 10 | 10 |
| G | 50 | 50 | 30 | 30 | 50 | 50 | 30 | 50 | 50 |
| Phosphorus | 0.2 | 1.5 | 0.68 | 0.68 | 0 | 0 | 2.5 | 0.2 | 0.1 |
| content % | | | | | | | | | |
| Bromine | 12 | 5 | 8.6 | 8.6 | 14.2 | 9.5 | 0 | 4.3 | 12 |
| content % | | | | | | | | | |

The preparation methods and material manufacturers in Comparative Examples 6 and 7 are listed as follows.

### Comparative Example 6

23 parts by weight of synthetic rubber (trade name Nipol 1072CGX, from ZEON), 25 parts by weight of brominated epoxy (trade name DER530A80, from DOW), 21 parts by weight of high bromine epoxy (trade name EPICLON 153-60M, from DAINIPPON INK & CHEMICALS), 25 parts by weight of biphenyl epoxy (trade name NC3000H, from Nippon Kayaku), 0.2 part by weight of 2E4MI (from Shikoku Chemicals), 10.1 parts by weight of aromatic diamine: 4,4-DDS (from Yinsheng Taiwan), 20 parts by weight of phenoxyphosphazene (SPB-100, having a phosphorus content of 13.4%, from Albemarle Corporation), 15 parts by weight of aluminum hydroxide (from Albemarle Corporation), 31 parts by weight of boehmite (from Bengbu Xinyuan Quartz Material Limited Company), 8 parts by weight of barium sulfate(Guizhou Redstar), solvent MEK to adjust the solid content to 66%.

Calculation: having a bromine content of 12.0% and a phosphorus content of 0.2%; the filler proportion and ratio were the same as those in Example 1.

### Comparative Example 7

33 parts by weight of nitrile rubber-modified epoxy (SC-024, from SHIN-A), 67 parts by weight of brominated epoxy resin (DEBR530A80, from DOW), 3 parts by weight of dicyandiamide, 0.02 part by weight of 2-methylimidazole, 6 parts by weight of tetrabromobisphenol A, 31 parts by weight of phosphorus-containing phenolic aldehyde (LC950, from SHIN-A), 17 parts by weight of aluminum hydroxide (from Albemarle Corporation), 34 parts by weight of boehmite (from Bengbu Xinyuan Quartz Material Limited Company), 9 parts by weight of barium sulfate (from Guizhou Redstar), solvent MEK to adjust the solid content to 66%.

Calculation: having a bromine content of 12.0% and a phosphorus content of 0.2%; the filler proportion and ratio were the same as those in Example 1.

TABLE 2

| | | | | | | | | | Comp. | | Comp. | | Comp. | | Comp. | | Comp. | | Comp. | | Comp. | |
|---|---|---|---|---|---|---|---|---|---|---|---|---|---|---|---|---|---|---|---|---|---|---|
| | Example | | Example | | Example | | Example | | Example | | Example | | Example | | Example | | Example | | Example | | Example | |
| Test items | 1 | | 2 | | 3 | | 4 | | 1 | | 2 | | 3 | | 4 | | 5 | | 6 | | 7 | |
| Tg (DSC) | 135 | | 137 | | 136 | | 136 | | 137 | | 137 | | 135 | | 136 | | 136 | | 112 | | 131 | |
| (° C.) | | | | | | | | | | | | | | | | | | | | | | |
| CTI(V) | 600 | | 600 | | 600 | | 200 | | 500 | | 600 | | 600 | | 600 | | 600 | | 525 | V | 550 | V |
| Solder | >600 | s | >600 | s | >600 | s | >600 | s | <500 | s | >600 | s | <560 | s | >600 | s | >600 | s | <300 | s | <300 | s |
| dipping | | | | | | | | | | | | | | | | | | | | | | |
| resistance | | | | | | | | | | | | | | | | | | | | | | |
| time | | | | | | | | | | | | | | | | | | | | | | |
| PCT water | 0.23 | | 0.26 | | 0.23 | | 0.25 | | 0.23 | | 0.22 | | 0.38 | | 0.23 | | 0.26 | | 0.55 | | 0.58 | |
| absorption % | | | | | | | | | | | | | | | | | | | | | | |
| Td 5% | 344 | | 355 | | 350 | | 345 | | 335 | | 349 | | 360 | | 355 | | 344 | | 348 | | 344 | |
| Flammability | V-0 | | V-0 | | V-0 | | V-0 | | V-0 | | V-1 | | V-0 | | V-1 | | V-1 | | V-0 | | V-0 | |
| Drilling | Good | | Good | | Good | | Good | | General | | Good | | General | | Good | | General | | Good | | Good | |
| Breakdown | 45+ | kV | 45+ | kV | 45+ | kV | 45+ | kV | 45+ | kV | 45+ | kV | 45+ | kV | 45+ | kV | 45+ | kV | 40+ | kV | 40+ | kV |
| voltage | | | | | | | | | | | | | | | | | | | | | | |

According to Tables 1-2, the followings can be seen.

(1) According to Examples 1-4, it can be seen that the epoxy resin compositions in Examples 1-4 all could achieve the flame retardancy of UL 94 V-0 level, and have a solder dipping resistance time of greater than 600 s and a better drilling processability.

(2) According to Examples 1-4, it could be seen that the epoxy resin compositions in Examples 1-3 all had a Comparative Tracking Index (CTI) of 600V, while the epoxy resin composition in Example 4 had a Comparative Tracking Index (CTI) of 200V, which showed that the addition of a suitable amount of filler into the epoxy resin composition could make the substrate have a high CTI.

(3) As compared to Comparative Example 3, the PCT water absorptions in Examples 1-4 were better than that in Comparative Example 3. Since only phosphorus-containing phenolic aldehyde was used in Comparative Example 3, and the phosphorus content was as high as 2.5%, the moisture absorption thereof was increased. In Examples 1-4, phosphorus-containing phenolic aldehyde and brominated bisphenol A were both used, and low moisture absorption could be achieved when the phosphorus content was only 0.2%-1.5%, which showed that the substrates could have a low water absorption when phosphorus-containing phenolic aldehyde and brominated bisphenol A were used in combination.

(4) As compared to Comparative Example 2, Examples 2-4 disclosed that phosphorus and bromine were used synergistically for flame retardancy, and only less than 10% of bromine was needed to achieve the UL94 V-0 level. Comparative Example 2 disclosed only introducing bromine for flame retardancy. Although the bromine content reached 9.5%, it could not achieve the UL94 V-0 level.

(5) As compared to Comparative Example 1, Examples 1-4 disclosed that, since phosphorus and bromine were used synergistically for flame retardancy, only 12% or less of bromine was needed to achieve the UL94 V-0 level. Thus, Examples 1-4 had better chemical heat resistance than Comparative Example 1, i.e. 5% thermal weight loss temperature being 9° C. higher than that in Comparative Example 1, and longer solder dipping resistance time.

(6) Comparative Examples 4 and 5 respectively disclosed the circumstances in which the bromine content and phosphorus content were not within the range of the present invention. It could be seen that, when the bromine content was 4.3%, and the phosphorus content was 0.2%, the flame retardancy could not achieve the UL94 V-0 level although the CTI and heat resistance were good. When the bromine content was 12%, and the phosphorus content was 0.1%, the flame retardancy could not achieve the UL94 V-0 level although the CTI of the material reached 600V.

(7) Comparative Examples 6 and 7 respectively disclosed the resin compositions in CN 101808466A and CN 101892027A could not reach a CTI of 600V when having the same bromine content, phosphorus content and filler system as the present invention. Moreover, the water absorption was obviously higher than that of the present invention. In contrast, the present invention has a more excellent pressure resistance.

In conclusion, the epoxy resin composition of the present invention has a greatly increased heat resistance as compared to pure bromine flame retardant system, and has a CTI of 600V or higher after the filler such as boehmite is added. As compared to pure phosphorus flame retardant system, the epoxy resin composition has a lower water absorption, a better drilling processability and a better flame retardancy. The prepregs and CCLs prepared from said epoxy resin composition have excellent CTI property, so as to significantly improve the adaptability of PCBs in harsh environments. Meanwhile, relatively higher thermal resistance and longer solder dipping resistance time make the epoxy resin composition be suitable for the needs of lead-free soldering. Moreover, the present invention can further reduce the dependence of flame retardancy on bromine, so as to be more environmentally friendly.

The applicant claims that the present invention describes the detailed process of the present invention, but the present invention is not limited to the detailed process of the present invention. That is to say, it does not mean that the present invention shall be carried out with respect to the above-described detailed process of the present invention. Those skilled in the art shall know that any improvements to the present invention, equivalent replacements of the raw materials of the present invention, additions of auxiliary, selections of any specific ways all fall within the protection scope and disclosure scope of the present invention.

1.-10. (canceled)

11. An epoxy resin composition comprising, based on the weight parts of organic solids,
(A) from 50 to 100 parts by weight of an epoxy resin,
(B) from 2 to 30 parts by weight of a phosphorus-containing phenolic aldehyde,
(C) from 1 to 40 parts by weight of a brominated bisphenol A,
(D) from 10 to 60 parts by weight of other curing agent,
(E) from 0.05 to 1.0 part by weight of a curing accelerator,
wherein the bromine in the epoxy resin composition is in an amount of 5-12% of the weight sum of organic solids in the composition; the phosphorus in the epoxy resin composition is in an amount of 0.2-1.5% of the weight sum of organic solids in the composition.

12. The epoxy resin composition claimed in claim 11, wherein the bromine in the epoxy resin composition is in an amount of 5-10% of the weight sum of organic solids in the composition; the phosphorus in the epoxy resin composition is in an amount of 0.5-1.5% of the weight sum of organic solids in the composition.

13. The epoxy resin composition claimed in claim 11, wherein the phosphorus-containing phenolic aldehyde is a phosphorus-containing phenanthrene compound.

14. The epoxy resin composition claimed in claim 13, wherein the phosphorus-containing phenolic aldehyde is a phenolic resin corresponding to dihydro-9-oxo-10-phosphaphenanthrene.

15. The epoxy resin composition claimed in claim 11, wherein said phosphorus-containing phenolic aldehyde comprises at least one member selected from the group consisting of:

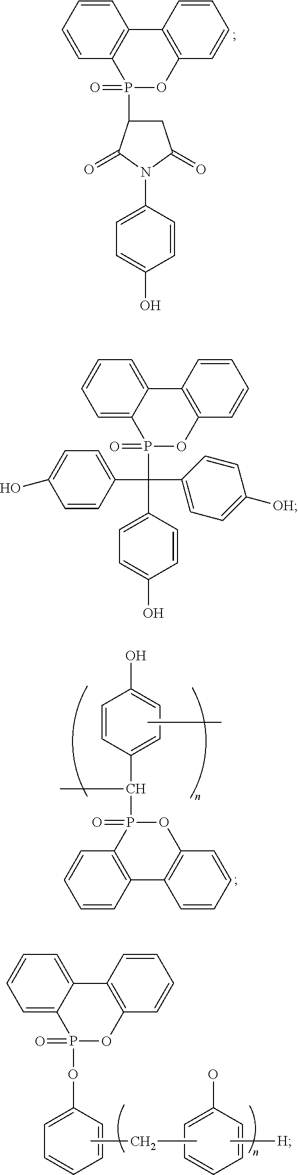

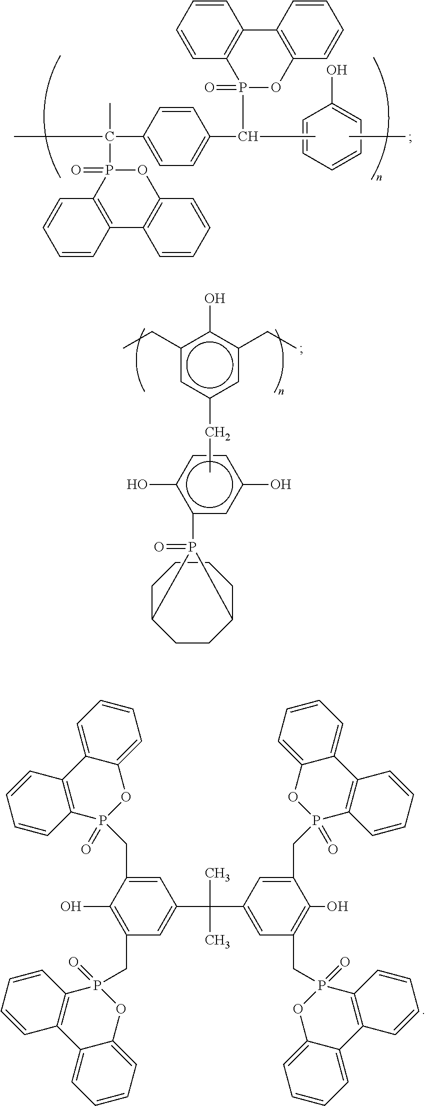

16. The epoxy resin composition claimed in claim 1, wherein said brominated bisphenol A has the following chemical structural formula: 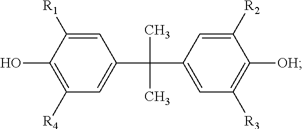
wherein at least one of R₁-R₄ is Br atom.

17. The epoxy resin composition claimed in claim 11, wherein said epoxy resin comprises at least one member selected from the group consisting of bisphenol A epoxy resin, o-cresol novolac epoxy resin, bisphenol A novolac epoxy resin, phenol epoxy resin, dicyclopentadiene epoxy resin, MDI epoxy resin, bisphenol F epoxy resin, bisphenol S epoxy resin, tetrafunctional epoxy resin, naphthalene epoxy resin and biphenyl epoxy resin.

18. The epoxy resin composition claimed in claim 11, wherein said other curing agent comprises at least one member selected from the group consisting of phenolic resin, aromatic diamine-based curing agent, dicyandiamide, aliphatic amine, acid anhydride, active polyester and cyanate.

19. The epoxy resin composition claimed in claim 18, wherein said phenolic resin comprises at least one member selected from the group consisting of phenol novolac resin, bisphenol A novolac resin, o-cresol novolac resin, triphenol novolac resin, naphthalene novolac resin, biphenyl novolac resin and dicyclopentadiene novolac resin.

20. The epoxy resin composition claimed in claim 18, wherein said aromatic diamine-based curing agent has the following chemical structural formula: 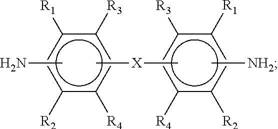
wherein X is selected from the group consisting of 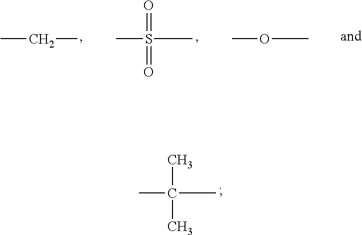
R₁, R₃ and R₄ are selected from the group consisting of H, —CH₃ and —C₂H₅; R₂ is selected from the group consisting of H, —CH₃ and —C₂H₅.

21. The epoxy resin composition claimed in claim 11, wherein said curing accelerator comprises at least one member selected from the group consisting of imidazole curing accelerator, organic phosphine curing accelerator and tertiary amine curing accelerator.

22. The epoxy resin composition claimed in claim 21, wherein said imidazole curing accelerator comprises at least one member selected from the group consisting of 2-methylimidazole, 2-methyl-4-ethylimidazole, 2-undecylimidazole, 2-phenylimidazole and 1-cyanoethyl-2-ethyl-4-methylimidazole;
wherein said organic phosphine curing accelerator comprises at least one member selected from the group consisting of tributylphosphine and triphenylphosphine; and
wherein said tertiary amine curing accelerator is benzyl dimethyl amine.

23. The epoxy resin composition claimed in claim 11, wherein the epoxy resin composition further comprises a filler.

24. The epoxy resin composition claimed in claim 23, wherein said filler comprises at least one member selected from the group consisting of boehmite, aluminum hydroxide, barium sulfate, calcium fluoride, magnesium hydroxide, silica, glass powder, kaolin, talc powder, mica powder, aluminum oxide, zinc oxide, magnesium oxide, boron nitride, aluminum nitride and calcium carbonate, or a mixture of at least two selected therefrom;
said filler has an average particle size of 0.3-20 μm;
said filler is in an amount of, based on the sum of organic solids of all components in the epoxy resin composition being 100 parts by weight, from 1 to 200 parts by weight.

25. The epoxy resin composition claimed in claim 11, wherein the epoxy resin composition further comprises a solvent.

26. The epoxy resin composition claimed in claim 25, wherein said solvent comprises at least one member selected from the group consisting of N,N′-dimethyl-formamide, ethylene glycol ethyl ether, propylene glycol methyl ether, acetone, butanone, methanol, ethanol, benzene and toluene.

27. A prepreg prepared by using the epoxy resin composition claimed in claim 11, comprising a base material, and the epoxy resin composition attached thereon after impregnation and drying.

28. A laminate comprising the prepreg claimed in claim 27.

29. A printed circuit board comprising the laminate claimed in claim 28.
